(19) United States
(12) Patent Application Publication
(10) Pub. No.: US 2026/0169914 A1
(43) Pub. Date: Jun. 18, 2026

(54) INFORMATION PROCESSING APPARATUS AND MEMORY SYSTEM

(71) Applicant: Kioxia Corporation, Tokyo (JP)

(72) Inventors: Atsushi KAWASUMI, Fujisawa Kanagawa (JP); Shinichi SASAKI, Ota Tokyo (JP)

(73) Assignee: Kioxia Corporation, Tokyo (JP)

(21) Appl. No.: 19/326,383

(22) Filed: Sep. 11, 2025

(30) Foreign Application Priority Data
Dec. 17, 2024 (JP) 2024-221133

(51) Int. Cl. G06F 12/02; G11C 16/04; G11C 16/10; G11C 16/26

(52) U.S. Cl. CPC G06F 12/0246; G11C 16/0483; G11C 16/10; G11C 16/26

(57) ABSTRACT

An information processing apparatus comprising a string connected to a first wiring and connected to a plurality of second wirings, wherein the string includes transistors connected in series, one end of the string connected to the first wiring, gates of the transistors connected to different second wirings, the transistors include a first transistor and a second transistor, the first transistor is set to a first threshold corresponding to first data, the second transistor is set to a second threshold corresponding to second data having a complementary relationship with the first data, two second wirings among the second wirings are connected to gates of the first transistor and the second transistor, one of the two second wirings is set to a potential level corresponding to third data, and another is set to a potential level corresponding to fourth data having a complementary relationship with the third data.

### CROSS REFERENCE TO RELATED APPLICATIONS

This application is based upon and claims the benefit of priority from the prior Japanese Patent Application No. 2024-221133, filed on Dec. 17, 2024, the entire contents of which are incorporated herein by reference.

### FIELD

An embodiment of the present invention relates to an information processing apparatus and a memory system.

### BACKGROUND

Natural language processing requires analyzing the meaning of sentences including a huge number of vocabularies and words, and when the natural language processing is performed by software, it takes a considerable time to obtain a result. Therefore, research to perform the natural language processing with hardware is in progress.

In a case where each vocabulary constituting a sentence handled by the natural language processing is expressed by a vector, the number of dimensions of the vector is the number of vocabularies, and words included in the vocabulary are element positions of the vector, since the number of words is overwhelmingly small with respect to the number of vocabularies, a sparse vector is obtained in which a frequency at which elements of each vector are non-zero is very small. By storing such a sparse vector in a semiconductor storage device and performing an inner product operation by hardware, it is possible to determine similarity between the vocabularies. However, storing a huge number of sparse vectors in the semiconductor storage device causes poor operation efficiency and wasteful consumption of hardware resources and power consumption.

### BRIEF DESCRIPTION OF THE DRAWINGS

FIG. 1 is a diagram in which an arbitrary sentence to be analyzed by natural language processing is expressed by a vector.

FIG. 2 is a diagram illustrating a vector of a vocabulary including a specific word.

FIG. 3 is a diagram illustrating an example in which an inner product operation of two sparse vectors is performed.

FIG. 4 is a diagram summarizing results of an inner product operation of two sparse vectors to be subjected to an inner product operation.

FIG. 5 is a circuit diagram illustrating an example of a string used for an inner product operation.

FIG. 6 is a diagram illustrating a first transistor and a second transistor in a string in a case of multi-valued data.

FIG. 7 is a diagram illustrating a relationship between a threshold and a gate voltage of the first transistor and the second transistor.

FIG. 8 is a diagram illustrating a result of an inner product operation of a 2-bit key and a 2-bit query in a comparative example.

FIG. 9 is a diagram illustrating a relationship between a threshold distribution and a gate voltage of a first transistor and a second transistor in the comparative example.

FIG. 10 is a diagram illustrating a result of an inner product operation of a 2-bit key and a 2-bit query in the present embodiment.

FIG. 11 is a diagram illustrating a relationship between a threshold distribution and a gate voltage of a first transistor and a second transistor according to the present embodiment.

FIG. 12 is a diagram illustrating a relationship between a threshold distribution and a gate voltage of a first transistor and a second transistor according to a modification of the present embodiment.

FIG. 13 is a diagram illustrating an example in which a current flowing through a string is changed according to a matched value of a key and a query.

FIG. 14 is a diagram illustrating an example of dividing a vector of a key and a query into a plurality of divided vectors.

FIG. 15 is a diagram illustrating connections between a plurality of divided strings corresponding to the plurality of divided vectors and a bit line BL.

FIG. 16 is a diagram illustrating a vector having n elements, in which a 254th element is an element “1” and other elements are “0”.

FIG. 17 is a diagram illustrating an example in which both a vector of a key and a vector of a query are represented by vectors similar to those in FIG. 16.

FIG. 18 is a diagram illustrating a result of performing an inner product operation between the two vectors in FIG. 17.

FIG. 19 is a circuit diagram of a string for comparing the key with the query in FIGS. 17 and 18.

FIG. 20 is a block diagram illustrating a schematic configuration of an information processing apparatus according to the present embodiment.

FIG. 21 is a circuit diagram illustrating an example in which a string is divided into two divided strings and connected to the same bit line.

FIG. 22 is a diagram illustrating an inner product value in a first example in which a string is divided into two divided strings.

FIG. 23 is a diagram illustrating an inner product value in a second example in which a string is divided into two divided strings.

FIG. 24 is a diagram illustrating an inner product value in a third example in which a string is divided into two divided strings.

FIG. 25 is a diagram illustrating an inner product value in a fourth example in which a string is divided into two divided strings.

### DETAILED DESCRIPTION

According to an information processing apparatus including a string connected to a first wiring and connected to a plurality of second wirings, wherein
the string includes a plurality of transistors connected in series, one end of the string connected to the first wiring, gates of the transistors connected to different second wirings,
the plurality of transistors include a first transistor and a second transistor,
the first transistor is set to a first threshold corresponding to first data,
the second transistor is set to a second threshold corresponding to second data having a complementary relationship with the first data,
two second wirings among the plurality of second wirings are connected to gates of the first transistor and the second transistor,
one of the two second wirings is set to a potential level corresponding to third data, and another is set to a potential level corresponding to fourth data having a complementary relationship with the third data, and
the string does not allow a current to flow when the first data and the third data match at a predetermined value, and allows the current to flow when the first data and the third data match at a value other than the predetermined value.

Hereinafter, an embodiment of an information processing apparatus and a memory system will be described with reference to the drawings. Although main components of the information processing apparatus and the memory system will be mainly described below, the information processing apparatus and the memory system may have components and functions that are not illustrated or described. The following description does not exclude components and functions that are not illustrated or described.

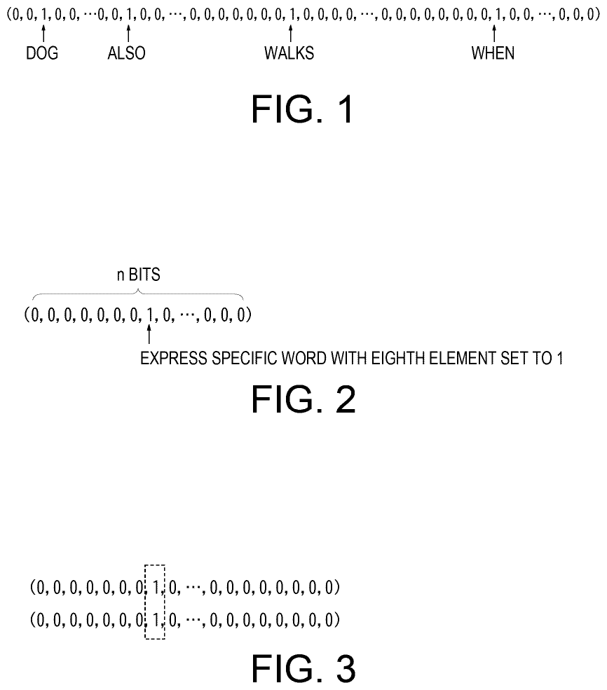

FIG. 1 is a diagram in which an arbitrary sentence to be analyzed by natural language processing is expressed by a vector. In the natural language processing, a sentence is projected onto a multidimensional space, each vocabulary constituting the sentence is expressed by a vector, the number of dimensions of the vector is the number of vocabularies, and words included in the vocabulary are element positions of the vector. For example, an element position of a vector for specifying an individual word is set to “1”, and the other elements are set to “0”.

FIG. 1 illustrates a vector representing a vocabulary of “when a dog also walks”. Each word such as “dog”, “also”, “walks”, and “when” is identified by the position of the element “1” in the vector.

As illustrated in FIG. 1, the vector handled in the natural language processing is a sparse vector in which the number of elements “1” is overwhelmingly smaller than the number of dimensions of the vector.

FIG. 2 is a diagram illustrating a vector of a vocabulary including a specific word. The vocabulary including a specific word is represented by a vector in which, for example, an eighth element in an n-dimensional vector (n is an integer of 1 or more) is set to “1”. The position of the element “1” in the vector varies for each type of word included in the vocabulary.

FIG. 3 is a diagram illustrating an example in which an inner product operation of two sparse vectors is performed. When two sparse vectors having the same number of dimensions include the same word, since the same element position is “1”, the result of the inner product operation is “1”, and it can be seen that two vocabularies include the same word.

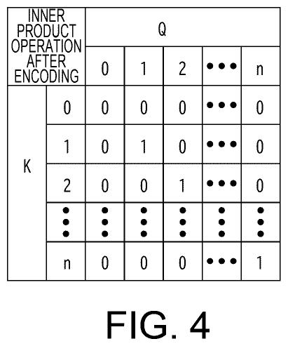

FIG. 4 is a diagram summarizing results of an inner product operation of two sparse vectors to be subjected to an inner product operation. FIG. 4 illustrates a result of an inner product operation in a case where the number of elements “1” included in each of the two sparse vectors having (n+1) elements is at most one. In FIG. 4, the two sparse vectors are referred to as a key K and a query Q. As illustrated in FIG. 4, when the same element position of the two sparse vectors corresponding to the key K and the query Q is “1”, an inner product value is “1”. In addition, the inner product value in a case where both of the two sparse vectors are zero, that is, have no element “1” is zero.

As described above, in a case where the inner product operation between the sparse vectors is performed, when all the elements of the sparse vectors are zero (all zero), the inner product value needs to be zero.

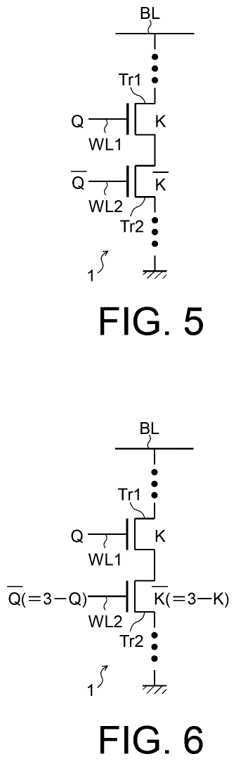

The inner product operation between the vectors can be performed by using a string in which a plurality of transistors are cascode-connected. FIG. 5 is a circuit diagram illustrating an example of a string 1 used for the inner product operation. The string 1 illustrated in FIG. 5 is, for example, a part of a memory cell array in a semiconductor storage device.

Here, the semiconductor storage device is, for example, a nonvolatile memory such as a NAND flash memory, a resistive random access memory (ReRAM), or a phase-change memory (PCM). Alternatively, the semiconductor storage device described above may be a volatile memory such as a dynamic RAM (DRAM) or a static RAM (SRAM). In the present specification, an example of using the string 1 of the NAND flash memory will be mainly described, but the string 1 may be configured using a semiconductor storage device other than the NAND flash memory.

The string 1 illustrated in FIG. 5 includes a plurality of cascode-connected transistors. FIG. 5 illustrates an example of the string 1 including a first transistor Tr1 and a second transistor Tr2 cascode-connected. The string 1 can be configured by cascode-connecting any number of transistors in addition to the first transistor Tr1 and the second transistor Tr2.

One end of the string 1 is connected to a bit line (first wiring) BL. Different word lines WL1 and WL2 are connected to gates of the first and second transistors Tr1 and Tr2 in the string 1. In the present specification, the plurality of word lines WL1, WL2, and the like may be collectively referred to as a word line WL.

The plurality of transistors in the string 1 store data supplied via the bit line BL in a state where the word line WL connected to each gate is set to a predetermined potential level. For example, in the case of the string 1 of the NAND flash memory, each transistor in the string 1 stores a charge corresponding to data in a floating gate or a charge storage film. By storing data in the transistor, a threshold of the transistor changes. When the threshold of the transistor changes, a gate potential level at which the transistor is turned on changes.

Among the plurality of transistors in each string 1, the first transistor Tr1 and the second transistor Tr2 are used to store a key K consisting of a plurality of bits. In the present embodiment, it is assumed that each bit of the key K is multi-valued data, but first, an example in which each bit of the key K is binary (0 or 1) will be described.

The value of each bit of the key K is stored in the first transistor Tr1 and the second transistor Tr2 in the separate strings 1. The first transistor Tr1 in each string 1 stores a value of a corresponding bit of the key K, and the second transistor Tr2 cascode-connected to the first transistor Tr1 stores a value having a complementary relationship with the value of the corresponding bit of the key K. The value having the complementary relationship is bit-inverted data. For example, when the first transistor Tr1 stores 0, the second transistor Tr2 stores 1. In the present specification, the key K consisting of a plurality of bits is referred to as first data, and complement data of the key K is referred to as second data.

In the present specification, the fact that the first transistor Tr1 stores 0 means that a threshold of the first transistor Tr1 is set to 0. In practice, the threshold of the first transistor Tr1 is set to a potential level corresponding to 0, but in the present specification, for the sake of simplicity, it is assumed that the threshold is set to 0.

Third data and fourth data are supplied to the two word lines WL1 and WL2 connected to the gates of the first transistor Tr1 and the second transistor Tr2 among the plurality of transistors in the string 1, respectively. The third data and the fourth data each consist of a plurality of bits, and the fourth data is data having a complementary relationship with the third data. That is, data obtained by inverting each bit of the third data is the fourth data. Each bit of the third data and the fourth data is assumed to be multi-valued data having a potential level of three values or more, but first, an example in which each bit of the third data and the fourth data is binary (0 or 1) will be described. The third data is a corresponding bit of the query Q. Each bit of the query Q is supplied on a different word line.

The information processing apparatus according to the present embodiment grasps whether the query Q input from the outside matches the key K stored in the plurality of strings 1 by the inner product operation, and outputs the result of the inner product operation via the bit line BL.

The query Q and the key K each consist of a plurality of bits and are compared in separate strings for each bit. In the present specification, the key K is referred to as first data, and the query Q is referred to as third data. In addition, data having a complementary relationship with the first data is referred to as second data, and data having a complementary relationship with the third data is referred to as fourth data.

As described above, the corresponding bit of the key K (first data) stored in the first transistor Tr1 and a corresponding bit of a key/K (second data) stored in the second transistor Tr2 have a complementary relationship with each other. For example, when the corresponding bit of the key K is “0”, the corresponding bit of the key/K is “1”. As described above, corresponding bits of the first data and the second data having a complementary relationship with each other are written in the first transistor Tr1 and the second transistor Tr2, so that the threshold of the first transistor Tr1 and a threshold of the second transistor Tr2 have different values. In the present specification, the threshold of the first transistor Tr1 is referred to as a first threshold, and the threshold of the second transistor Tr2 is referred to as a second threshold.

Although FIG. 5 illustrates an example in which each bit of the query Q and the key K is binary data, simply comparing binary data of each bit only results in a simple comparison between binary data. In recent nonvolatile memories, multi-valued data of three or more values can be stored in a memory cell, and a storage capacity of the nonvolatile memory is increased. By using the nonvolatile memory capable of storing such multi-valued data, even when each bit of the query Q and the key K is multi-valued data, the query Q and the key K can be compared, and the application range of the information processing apparatus according to the present embodiment is widened.

FIG. 6 is a diagram illustrating the first transistor Tr1 and the second transistor Tr2 in the string 1 in a case where each bit of the query Q and the key K is multi-valued data of four values consisting of two bits. In this case, each bit of the query Q and the key K can take four potential levels consisting of two bits. The key K (the first threshold of the first transistor Tr1) stored in the first transistor Tr1 and the key/K (the second threshold of the second transistor Tr2) stored in the second transistor Tr2 are in a complementary relationship, and when the first threshold of the first transistor Tr1 is K, the second threshold of the second transistor Tr2 is 3−K.

Similarly, since the query Q input to the gate of the first transistor Tr1 and a query/Q input to the gate of the second transistor Tr2 have a complementary relationship with each other, when the query Q input to the gate of the first transistor Tr1 is Q, the query/Q input to the gate of the second transistor Tr2 is represented by 3−Q.

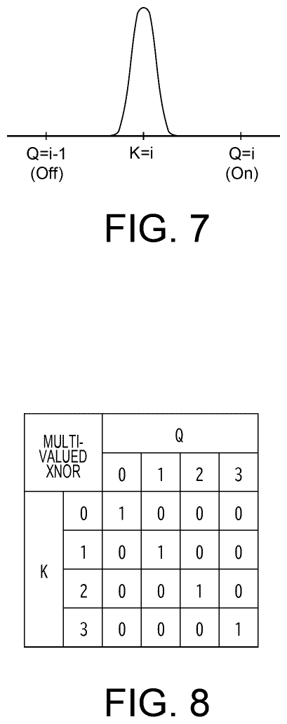

FIG. 7 is a diagram illustrating a relationship between the threshold value and the gate voltage of the first transistor Tr1 and the second transistor Tr2. The first threshold of the first transistor Tr1 in each string 1 is a value corresponding to the multi-valued data of the corresponding bit of the key K input via the bit line BL. Since a voltage level of a threshold slightly varies for each transistor, a potential level of the first threshold of the first transistor Tr1 varies within a predetermined range as illustrated in FIG. 7. This variation range is called a threshold distribution. The first transistor Tr1 is turned on when a potential level of the query Q input to the gate of the first transistor Tr1 is larger than the threshold distribution, and is turned off when the potential level of the query Q is smaller than the threshold distribution. The same applies to the second transistor Tr2.

From FIGS. 6 and 7, the first transistor Tr1 and the second transistor Tr2 are turned on only when both the following Equations (1) and (2) are satisfied.

$$Q \geq K \qquad ( 1 )$$

$$3 - Q \geq 3 - K \qquad ( 2 )$$

Equation (3) is obtained by modifying Equation (2).

$$Q \leq K \qquad ( 3 )$$

A condition that satisfies both Equation (1) and Equation (3) is represented by Equation (4).

$$Q = K \qquad ( 4 )$$

As described above, the first transistor Tr1 and the second transistor Tr2 in each string 1 are turned on only when the multi-valued data of the corresponding bits of the query Q and the key K match.

FIG. 8 is a diagram illustrating a result of an inner product operation of a 2-bit key K and a 2-bit query Q in a comparative example. As illustrated in FIG. 8, the key K and the query Q can take values of 0, 1, 2, or 3. The inner product value is “1” only when the values of the key K and the query Q match. That is, also in a case where both the key K and the query Q are “0”, the inner product value is “1”. In this manner, the result of the exclusive NOR (XNOR) operation performed on the key K and the query Q is the inner product value.

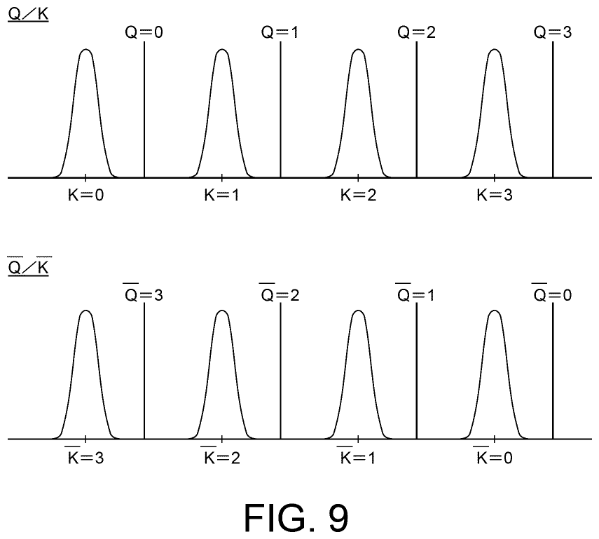

FIG. 9 is a diagram illustrating a relationship between a threshold distribution and a gate voltage of the first transistor Tr1 and the second transistor Tr2 in the comparative example. An upper part of FIG. 9 illustrates a relationship between the threshold distribution and the gate voltage of the first transistor Tr1, and a lower part of FIG. 9 illustrates a relationship between the threshold distribution and the gate voltage of the second transistor Tr2.

As illustrated in FIG. 9, when the query Q and the key K match, the gate voltages of the first transistor Tr1 and the second transistor Tr2 are set to be larger than the threshold. As a result, the first transistor Tr1 and the second transistor Tr2 are turned on, and a current flows through the string 1.

On the other hand, in the present embodiment, among the first transistor Tr1 and the second transistor Tr2 cascode-connected in the string 1, the first threshold corresponding to the first data is set to the first transistor Tr1, and the second threshold corresponding to the second data having a complementary relationship with the first data is set to the second transistor Tr2. One word line (second wiring) WL1 connected to the gate of the first transistor Tr1 is set to a potential level corresponding to the third data, and the other word line (second wiring) WL2 connected to the gate of the second transistor Tr2 is set to a potential level corresponding to the fourth data having a complementary relationship with the third data. In the string 1, when the first data and the third data match at a predetermined value (for example, all zero), no current is allowed to flow, and when the first data and the third data match at a value other than the predetermined value (for example, any element is “1”), a current is allowed to flow.

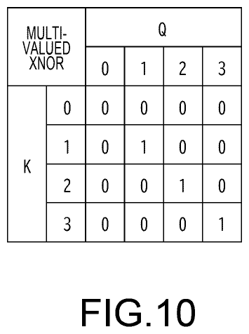

FIG. 10 is a diagram illustrating a result of an inner product operation of a 2-bit key K and a 2-bit query Q in the present embodiment. The present embodiment is different from FIG. 8 in that the inner product value is set to “0” when both the key K and the query Q are “0”.

As described above, in the present embodiment, even when the key K and the query Q match, the inner product value is not necessarily “1”. In a case where the key K and the query Q match at “0”, the inner product value is “0”. In a case where the key K and the query Q match at a value other than “0”, the inner product value is “1”.

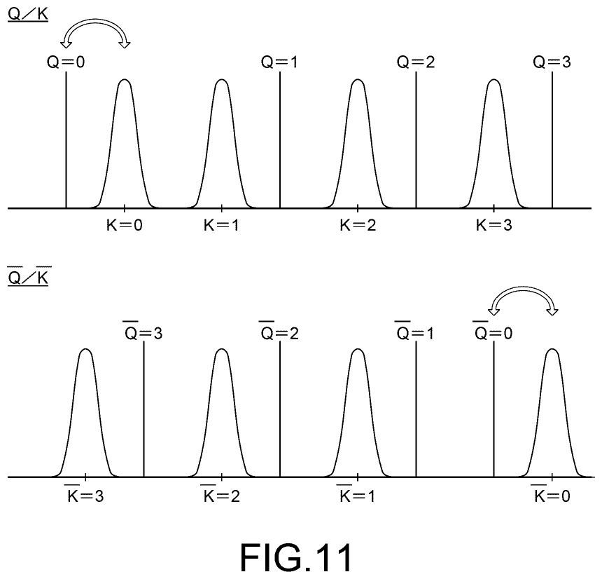

FIG. 11 is a diagram illustrating a relationship between a threshold distribution and a gate voltage of the first transistor Tr1 and the second transistor Tr2 according to the present embodiment. An upper part of FIG. 11 illustrates a relationship between a threshold distribution and a gate voltage of the first transistor Tr1, and a lower part illustrates a relationship between a threshold distribution and a gate voltage of the second transistor Tr2.

In a case where the key K and the query Q match at a value other than “0”, the gate voltages of the first transistor Tr1 and the second transistor Tr2 are set to be larger than the threshold. As a result, the first transistor Tr1 and the second transistor Tr2 are turned on, and a current flows through the string 1.

In a case where the key K and the query Q match at “0”, the gate voltages of the first transistor Tr1 and the second transistor Tr2 are set to be smaller than the threshold. As a result, the first transistor Tr1 and the second transistor Tr2 are turned off, and no current flows through the string 1.

As described above, in the example of FIG. 11, when the key K and the query Q match at a predetermined value (for example, all zero), the gate voltage of the first transistor Tr1 is made lower than the threshold (first threshold) of the first transistor Tr1, and the gate voltage of the second transistor Tr2 is made lower than the threshold (second threshold) of the second transistor Tr2. When the key K and the query Q match at a value other than “0”, the gate voltage of the first transistor is set to a voltage level higher than the first threshold, and the gate voltage of the second transistor Tr2 is set to a voltage level higher than the second threshold.

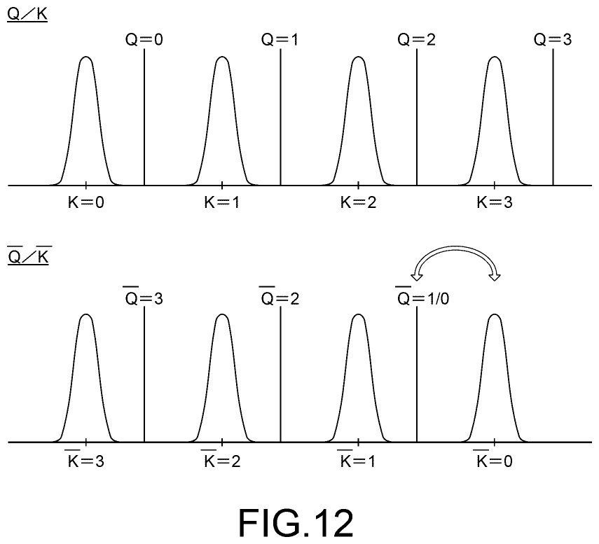

The relationship between the threshold distribution and the gate voltage of the first transistor Tr1 and the second transistor Tr2 in the present embodiment is not necessarily as illustrated in FIG. 11. FIG. 12 is a diagram illustrating a relationship between a threshold distribution and a gate voltage of the first transistor Tr1 and the second transistor Tr2 according to a modification of the present embodiment. An upper part of FIG. 12 illustrates a relationship between a threshold distribution and a gate voltage of the first transistor Tr1, and a lower part illustrates a relationship between a threshold distribution and a gate voltage of the second transistor Tr2.

The relationship between the threshold distribution and the gate voltage of the first transistor Tr1 in the modification is the same as the relationship between the threshold distribution and the gate voltage of the first transistor Tr1 in the comparative example of FIG. 9. The relationship between the threshold distribution and the gate voltage of the second transistor Tr2 in the modification is different from that of the comparative example in FIG. 9 in that the gate voltage of the second transistor Tr2 is lower than the threshold when the key K and the query Q match at “0”. In the modification, the gate voltage when the query Q is “0” is made the same as the gate voltage when the query Q is “1”. As a result, when the key K and the query Q match at “0”, the second transistor Tr2 is turned off, and no current flows through the string 1. Further, by making the gate voltage when the query Q is “0” the same as the gate voltage when the query Q is “1”, the voltage control of the word line WL becomes easy.

In FIG. 12, the relationship between the threshold distribution and the gate voltage of the first transistor Tr1 is the same as that in the comparative example of FIG. 9, and the relationship between the threshold distribution and the gate voltage of the second transistor Tr2 is such that the gate voltage of the second transistor Tr2 when the key K and the query Q match at “0” is lower than the threshold. However, the relationship between the threshold distribution and the gate voltage of the second transistor Tr2 may be the same as that in the comparative example of FIG. 9, and the relationship between the threshold distribution and the gate voltage of the first transistor Tr1 may be such that the gate voltage of the first transistor Tr1 when the key K and the query Q match at “0” is lower than the threshold.

As described above, in the modification of FIG. 12, in a case where the key K and the query Q match at a predetermined value (for example, all zero), one of the first transistor Tr1 and the second transistor Tr2 is turned off and the other is turned on. When the key K and the query Q match at a value other than “0”, the gate voltage of the first transistor is set to a voltage level higher than the first threshold, and the gate voltage of the second transistor Tr2 is set to a voltage level higher than the second threshold. More specifically, the potential level (fourth data) of the word line WL2 among the two word lines WL1 and WL2 in a case where the second transistor Tr2 is turned on when the first data (key) is “1” is set to be the same as the potential level (fourth data) of the word line WL2 in a case where the second transistor Tr2 is turned off when the first data is “0”.

### Multi-Value Conversion

As described above, in the present embodiment, it is assumed that the first transistor Tr1 and the second transistor Tr2 in the string 1 store multi-valued data. For example, in a case where both the key K and the query Q have two bits, any one of the four thresholds corresponding to the key K can be set to each of the first transistor Tr1 and the second transistor Tr2. A current corresponding to a difference between the threshold and the gate voltage flows through the first transistor Tr1 and the second transistor Tr2. More specifically, the larger the gate voltage is than the threshold of the first transistor Tr1 and the second transistor Tr2, the larger the flowing current is.

In a case where the first transistor Tr1 and the second transistor Tr2 store the multi-valued data corresponding to the key K, the current flowing through the string 1 is made different by a matched value of the key K and the query Q, so that the matched value of the key K and the query Q can be estimated by the current flowing through the string 1.

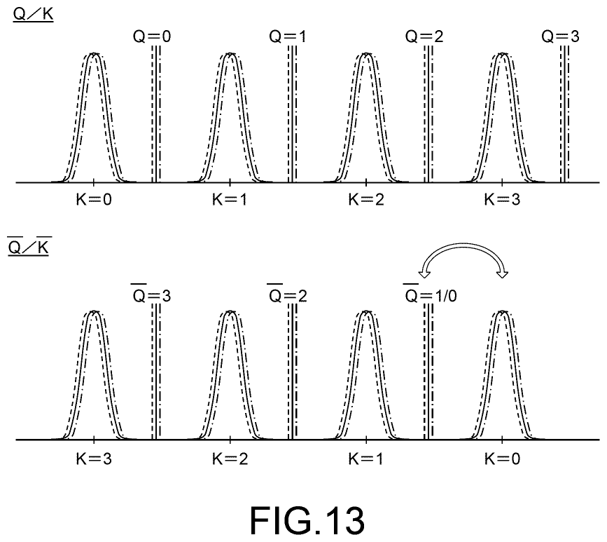

FIG. 13 is a diagram illustrating an example in which the current flowing through the string 1 is changed by the matched value of the key K and the query Q. An upper part of FIG. 13 illustrates a relationship between the threshold distribution and the gate voltage of the first transistor Tr1. A lower part illustrates a relationship between the threshold distribution and the gate voltage of the second transistor Tr2.

As illustrated in FIG. 13, by controlling at least one of the threshold or the gate voltage of the first transistor Tr1 and the second transistor Tr2 by the matched value of the key K and the query Q, the current flowing through the string 1 can be changed by the matched value of the key K and the query Q.

For example, when the key K and the query Q match at “1”, the current flowing through the string 1 is reduced as compared with a case of matching at “3”. For this purpose, in a case where the key K and the query Q match at “1”, the difference between the threshold voltage and the gate voltage of at least one of the first transistor Tr1 or the second transistor Tr2 may be made smaller than that in a case where the key K and the query Q match at “3”.

The current flowing through the string 1 can be variably controlled by adjusting at least one of the threshold levels of the first transistor Tr1 and the second transistor Tr2 or the gate voltages of the first transistor Tr1 and the second transistor Tr2. Therefore, by adjusting at least one of the threshold level or the gate voltage by the matched value of the key K and the query Q, the current flowing through the string 1 can be changed by the matched value of the key K and the query Q. As a result, the matched value of the key K and the query Q can be accurately estimated by the current flowing through the string 1.

### Division of Vector

In performing the inner product operation of the vector of the key K and the vector of the query Q, in a case where each vector includes a plurality of elements “1”, the inner product operation cannot be correctly performed. For example, when two vectors include two elements “1” and the element positions of these two elements “1” are the same in the two vectors, the inner product value is 2 when the inner product operation of the two vectors is performed, but the current flowing through the string 1 is not twice the current when one element “1” is matched between the two vectors. This is because in the string 1, a plurality of sets each including the first transistor Tr1 and the second transistor Tr2 as one set are cascode-connected, and only a minimum value of the current flowing through each set flows through the string 1.

Therefore, in a case where a plurality of elements “1” are included in the vector of the key K and the vector of the query Q, it is desirable to divide these vectors so that one element “1” is included in each divided vector. In this case, the string 1 is divided into a plurality of strings 1, and one end of each divided string is connected to the same bit line BL. As a result, since a sum of the currents flowing through each divided string flows through the bit line BL, matching detection between the vectors including the plurality of elements can be correctly performed by the current or the potential of the bit line BL.

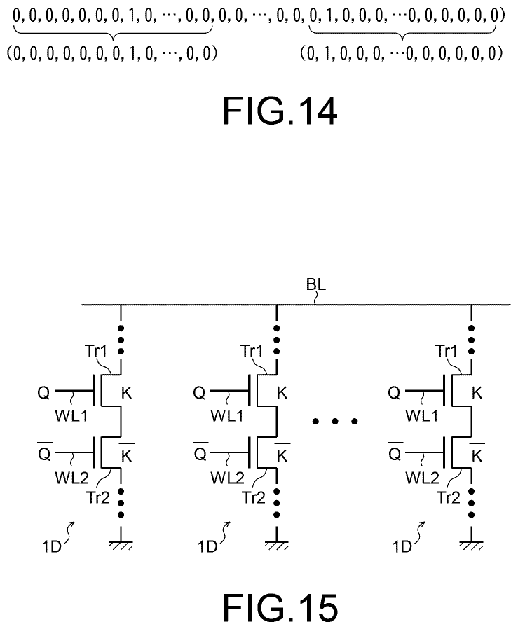

FIG. 14 is a diagram illustrating an example of dividing the vector of the key K and the query Q into a plurality of divided vectors. It is important to include at most one element “1” in each divided vector in order to eliminate errors.

FIG. 15 is a diagram illustrating connections between a plurality of divided strings 1D corresponding to the plurality of divided vectors and the bit line BL. As illustrated in FIG. 15, one end of each of the plurality of divided strings 1D is connected to the common bit line BL. In each divided string 1D, the inner product operation of the corresponding divided key K and divided query Q is performed. Since the vector of the divided key K and the vector of the divided query Q include at most one element “1”, when the divided key K and the divided query Q match, a current flows through the corresponding divided string 1D. As the number of divided strings 1D through which the current has flowed is larger among the plurality of divided strings 1D, the current flowing through the bit line BL is further increased, and the potential of the bit is further lowered. Therefore, the inner product operation of the vector of the key K and the vector of the query Q including the plurality of elements “1” can be performed by the current or the potential of the bit line BL.

In this manner, in a case where the number of bits of the vectors of the key K and the query Q exceeds a predetermined bit length, or in a case where a ratio of bits taking a value other than “0” (for example, “1”) included in the vectors of the key K and the query Q exceeds a predetermined value, it is desirable to divide the vector so that the number of elements taking values other than the predetermined value (for example, “1”) included in the divided vector becomes 1 or less.

### Conversion of Element Position from Decimal Number to m-Ary Number (m Is Integer Less Than 10 and 2 or More)

As described above, in the natural language processing, for example, the number of vocabularies of the sentence is set as the number of dimensions of the vector, and words included in each vocabulary constituting the sentence are identified by element positions of the vector. When the number of element positions is large (for example, 254), it is difficult to express the vector with the string 1 in a semiconductor storage device such as a NAND flash memory.

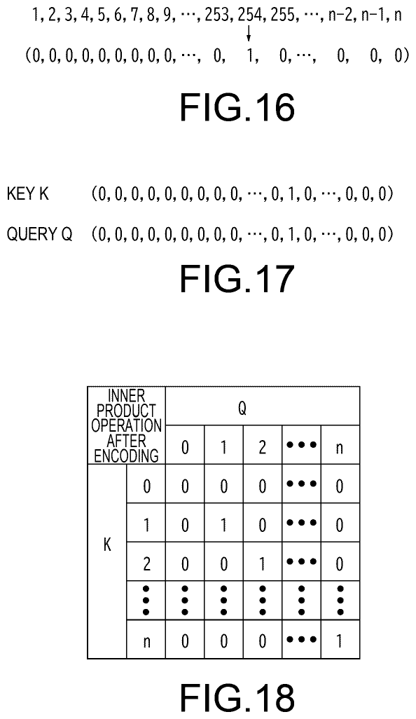

FIG. 16 is a diagram illustrating a vector having n (n is an integer of 255 or more) elements, in which a 254th element is an element “1” and the other elements are “0”. FIG. 17 is a diagram illustrating an example in which both the vector of the key K and the vector of the query Q are represented by vectors similar to those in FIG. 16.

FIG. 18 is a diagram illustrating a result of performing an inner product operation between the two vectors in FIG. 17. As illustrated, when the element positions of the element “1” of the two vectors match, the inner product value is “1”. In addition, the inner product value in a case where the two vectors are both zero is “0”.

Since it is not realistic to configure the string 1 by cascode-connecting the first and second transistors of more than 254 sets, it is difficult to perform an inner product operation between multidimensional vectors in a NAND flash memory or the like as it is. Therefore, in the present embodiment, 254 is replaced with, for example, a quaternary number. The decimal number 254 is “3332” in the quaternary number. The quaternary number “3332” can be expressed by four cascode-connected transistors. Each set of transistors stores two bits of data.

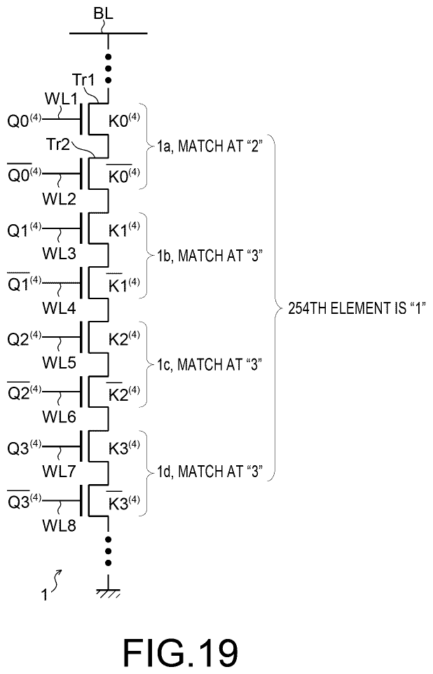

FIG. 19 is a circuit diagram of the string 1 for comparing the key K and the query Q in FIGS. 17 and 18. The string 1 of FIG. 19 is configured by cascode-connecting a plurality of sets of first transistors Tr1 and second transistors Tr2 with the first transistor Tr1 and the second transistor Tr2 as one set. Each of the plurality of sets allows a current to flow when two vectors representing the key K and the query Q match except for all zeros.

The string 1 of FIG. 19 includes four sets of first and second transistors Tr1 and Tr2 cascode-connected. A first set 1a corresponds to a least significant digit of the quaternary number, a second set 1b corresponds to a second digit from the least significant digit, a third set 1c corresponds to a third digit from the least significant digit, and a fourth set 1d corresponds to a most significant digit. The first set 1a to the fourth set 1d in the string 1 compare the key K and the query Q for corresponding digits of the quaternary value representing the element position of the element “1”.

The first set 1a allows a current to flow in a case where the key K and the query Q are “2”. In the second set 1b to the fourth set 1d, a current flows in a case where the key K and the query Q are “3”.

As described above, each digit of the value obtained by converting the element position of the element “1” of the vector into the quaternary number is allocated to each set of the string 1, and it is detected whether the key K and the query Q match the value of each digit, whereby the inner product operation of the key K and the query Q can be performed without complicating the configuration of the string 1 even when the element position of the element “1” is a large value.

Note that although FIG. 19 illustrates an example in which the value of the element position of the decimal number is converted into the quaternary number, the value may be converted into an m-ary value (m is an integer of less than 10 and 2 or more) other than the quaternary number. In this case, first transistors and second transistors of sets of the number of digits of the m-ary value are cascode-connected to the string 1. The first threshold and the second threshold according to the value of the corresponding digit of the m-ary value are set to the first transistor Tr1 and the second transistor Tr2 of each set of the string 1. The string allows a current to flow when each of the plurality of pieces of third data input to the plurality of sets is equal to the first data corresponding to the first threshold and each of the plurality of pieces of fourth data input to the plurality of sets is equal to the second data corresponding to the second threshold.

### Memory System

The information processing apparatus 10 according to the present embodiment can be incorporated in a memory system using a NAND flash memory or the like.

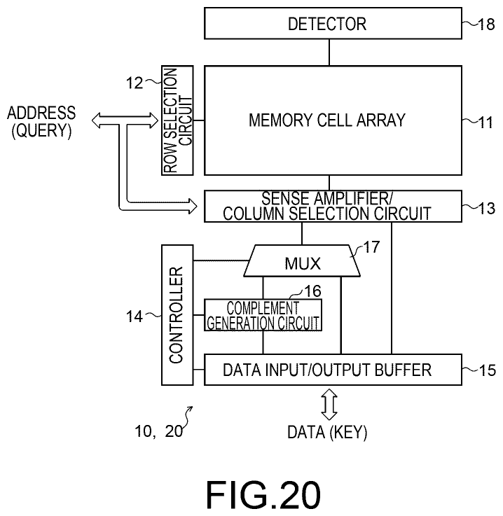

FIG. 20 is a block diagram illustrating a schematic configuration of the information processing apparatus 10 according to the present embodiment. The information processing apparatus 10 in FIG. 20 includes a memory cell array 11, a row selection circuit 12, a sense amplifier/column selection circuit 13, a controller 14, a data input/output buffer 15, a complement generator 16, and a multiplexer 17.

Similarly to FIG. 15, the memory cell array 11 has a plurality of strings 1 connected to the same bit line BL. A plurality of bit lines BL may be arranged in the memory cell array 11. In this case, a plurality of strings 1 similar to those in FIG. 15 are provided for each bit line BL. Similarly to FIG. 1, each string 1 includes a first transistor Tr1 and a second transistor Tr2, and a word line WL set to a potential level corresponding to the query Q is connected to each gate of the first transistor Tr1 and the second transistor Tr2.

In addition to the first transistor Tr1 and the second transistor Tr2, a plurality of transistors are cascode-connected to each string 1. The plurality of transistors are set to an ON state when the current of the string 1 is read.

The row selection circuit 12 sets the potential level of the word line WL connected to each gate of the first transistor Tr1 and the second transistor Tr2 according to the query Q supplied from the outside according to an instruction from the controller 14.

The data input/output buffer 15 acquires the key K from the outside, and supplies the acquired key K to the complement generator 16 and the multiplexer 17 according to the instruction from the controller 14. The complement generator 16 inverts the key K from the data input/output buffer 15 for each bit to generate complement data of the key K. In accordance with the instruction from the controller 14, the multiplexer 17 selects either the key K from the data input/output buffer 15 or the complement data of the key K generated by the complement generator 16, and supplies it to the sense amplifier/column selection circuit 13. Note that the complement generator and the multiplexer may be similarly provided on the row selection circuit 12 side to which an address (query) is input. In accordance with the instruction from the controller 14, the multiplexer can select either the query Q to be input or complement data of the query Q generated by the complement generator 16 and supply it to the word line WL via the row selection circuit 12.

The sense amplifier/column selection circuit 13 supplies the key K or the complement data output from the multiplexer 17 to the bit line BL.

The memory cell array 11, the row selection circuit 12, the sense amplifier/column selection circuit 13, the controller 14, the data input/output buffer 15, the complement generator 16, and the multiplexer 17 illustrated in FIG. 20 can also be used as the memory system 20.

The information processing apparatus 10 in FIG. 20 may include a detector 18. The detector 18 detects at least one of a current flowing through the bit line BL or a voltage of the bit line BL. The detector 18 may output a digital signal obtained by analog-digital conversion of at least one of the current flowing through the bit line BL or the voltage of the bit line BL to the outside.

The information processing apparatus 10 of FIG. 20 may be able to select either a mode in which the memory cell array 11 is used as a normal memory or a mode in which the key K is stored in the memory cell array 11 and comparison with the query Q is performed.

In addition, the memory cell array 11 may include a memory cell area for storing the key K and comparing with the query Q, and a memory cell area used as a normal memory.

As described above, since the processing operation similar to that of the information processing apparatus 10 according to the present embodiment can be performed by using the semiconductor storage device having a configuration substantially equivalent to that of a normal memory, design is easy, and the information processing apparatus 10 can be constructed using an existing semiconductor process in a short design time.

### Reduction of Error When Vector Includes Plurality of Elements “1”

As described above, when the vector includes a plurality of elements “1”, an error can be reduced by dividing the string 1 into a plurality of divided strings 1D.

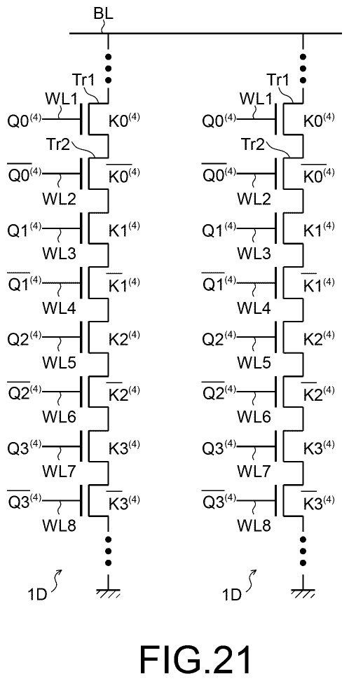

FIG. 21 is a circuit diagram illustrating an example in which the string 1 is divided into two divided strings 1D and connected to the same bit line BL.

It is assumed that the original string 1 includes up to two non-zero elements. Hereinafter, an example in which the non-zero is “1” will be mainly described.

In FIG. 21, one end of each of the two divided strings 1D is connected to the same bit line BL. Each divided string 1D includes a plurality of sets of cascode-connected first transistors Tr1 and second transistors Tr2. Each divided string 1D allows a current to flow when the element positions of up to one element “1” are the same in the key K and the query Q. Each digit of a value obtained by converting the element position of the element “1” into a quaternary number is associated with any set of the divided strings 1D.

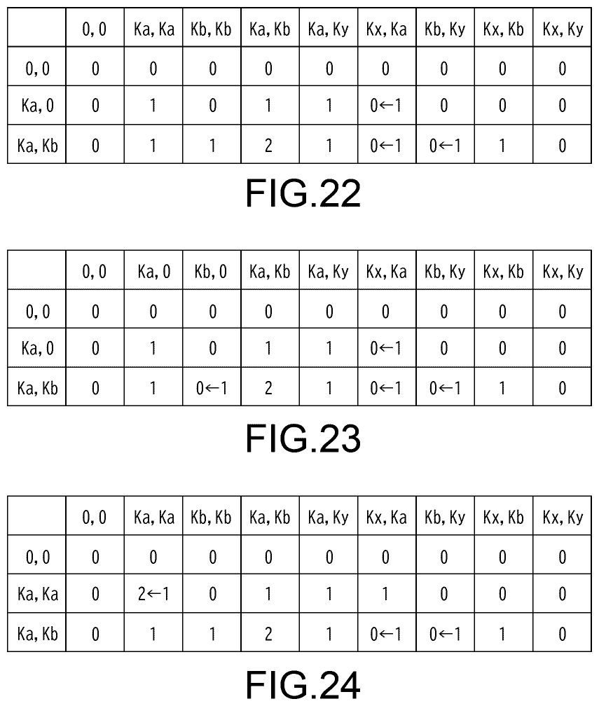

FIG. 22 is a diagram illustrating an inner product value in a first example in which the string 1 is divided into two divided strings 1D. In FIG. 22, the element positions of the non-zero elements provided one by one in the two divided strings 1D are Ka and Kb, and Ka>Kb>0 is satisfied.

In the first example, it is assumed that combinations of keys K stored one by one in the two divided strings 1D are (0,0), (Ka, 0), and (Ka, Kb). It is assumed that the queries Q corresponding to the keys K are (0,0), (Ka, Ka), and (Ka, Kb). Among the data of the queries Q input to the two divided strings 1D, values that do not match Ka, Kb, and 0 are Kx and Ky.

In this case, the combination of the queries Q input to the two divided strings 1D can take (0,0), (Ka, Ka), (Kb, Kb), (Ka, Kb), (Ka, Ky), (Kx, Ka), (Kb, Ky), (Kx, Kb), and (Kx, Ky).

In this case, among all the combinations of the key K and the query Q, the inner product values of (Ka, 0)×(Kx, Ka), (Ka, Kb)×(Kx, Ka), and (Ka, Kb)×(Kb, Ky) become incorrect values. For example, in (Ka, 0)×(Kx, Ka), a portion where the inner product value should be “1” is “0”. Similarly, in (Ka, Kb) ×(Kx, Ka), a portion where the inner product value should be “1” is “0”. Similarly, in (Ka, Kb)×(Kb, Ky), a portion where the inner product value should be “1” is “0”.

The reason why an error occurs in the inner product value of the key K and the query Q in this manner is that, since the two keys K are stored separately in the two divided strings 1D, the operation result of the inner product value in the two divided strings 1D changes depending on how the query Q is given.

However, for example, in a case where an inner product value is calculated with one string 1 without division, such as an inner product value of (Ka, Kb)×(Ka, Kb)=2, the value that would be incorrect can be calculated correctly. Therefore, when the inner product value is obtained using the divided string 1D, the frequency of errors can be reduced as compared with the case of obtaining the inner product value in one string 1, but the errors cannot be completely eliminated.

FIG. 23 is a diagram illustrating an inner product value in a second example in which the string 1 is divided into two divided strings 1D. In the second example, queries Q different from those in the first example are given. The queries Q of the second example are assumed to be (0,0), (Ka, Ka), and (Ka, Kb). The keys K of the second example are the same as those in the first example.

In the second example, the query Q input to the two divided strings 1D can take (0,0), (Ka, 0), (Kb, 0), (Ka, Kb), (Ka, Ky), (Kx, Ka), (Kb, Ky), (Kx, Kb), and (Kx, Ky).

Among them, the inner product values of (Ka, Kb)×(Kb, 0), (Ka, Kb)×(Kx, Ka), (Ka, Kb)×(Kb, Ky), and (Ka, 0)×(Kx, Ka) become incorrect values. For example, in (Ka, Kb)×(Kb, 0), a portion where the inner product value should be “1” is “0”. Similarly, in (Ka, Kb)×(Kx, Ka), a portion where the inner product value should be “1” is “0”. Similarly, in (Ka, Kb)×(Kb, Ky), a portion where the inner product value should be “1” is “0”. Similarly, in (Ka, 0)×(Kx, Ka), a portion where the inner product value should be “1” is “0”.

FIG. 24 is a diagram illustrating an inner product value in a third example in which the string 1 is divided into two divided strings 1D. In the third example, a query Q different from that in the first example is given. The query Q of the third example is assumed to be (0,0), (Ka, Ka), and (Ka, Kb). The key K of the third example is the same as that in the first example.

The third example has a combination of the keys K different from those in the first example and the second example. It is assumed that combinations of the keys K of the third example are (0,0), (Ka, Ka), and (Ka, Kb). It is assumed that the queries Q corresponding to the keys K are (0,0), (Ka, Ka), and (Ka, Kb) as in the first example.

In the third example, the queries Q input to the two divided strings 1D can take (0,0), (Ka, Ka), (Kb, Kb), (Ka, Kb), (Ka, Ky), (Kx, Ka), (Kb, Ky), (Kx, Kb), and (Kx, Ky), similarly to the first example.

Among them, the inner product values of (Ka, Ka)×(Ka, Ka), (Ka, Kb)×(Kx, Ka), and (Ka, Kb)×(Kb, Ky) become incorrect values. For example, in (Ka, Ka)×(Ka, Ka), a portion where the inner product value should be “1” is “2”. Similarly, in (Ka, Kb)×(Kx, Ka), a portion where the inner product value should be “1” is “0”. Similarly, in (Ka, Kb)×(Kb, Ky), a portion where the inner product value should be “1” is “0”.

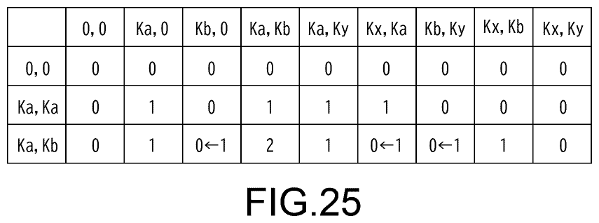

FIG. 25 is a diagram illustrating an inner product value in a fourth example in which the string 1 is divided into two divided strings 1D. In the fourth example, the same keys K and queries Q as those in the third example are given, but the queries Q input to the two divided strings 1D are different from those in the third example. In the fourth example, the queries Q input to the two divided strings 1D can take (0,0), (Ka, 0), (Kb, 0), (Ka, Kb), (Ka, Ky), (Kx, Ka), (Kb, Ky), (Ky, Kb), and (Kx, Ky).

Among them, the inner product values of (Ka, Kb)×(Kb, 0), (Ka, Kb)×(Kx, Ka), and (Ka, Kb)×(Kb, Ky) become incorrect values. For example, in (Ka, Kb)×(Kb, 0), a portion where the inner product value should be “1” is “0”. Similarly, in (Ka, Kb)×(Kx, Ka), a portion where the inner product value should be “1” is “0”. Similarly, in (Ka, Kb)×(Kb, Ky), a portion where the inner product value should be “1” is “0”.

As described above, in the present embodiment, the inner product operation between the sparse vectors can be performed at high speed using hardware of a small circuit scale. More specifically, by storing the key K in the string 1 of the semiconductor storage device and inputting the query Q via the word line WL, it is possible to output the inner product operation result by the potential or the current of the bit line BL connected to the string 1. When the sparse vectors are zero, the current is not allowed to flow through the string 1, so that the current can be allowed to flow through the string 1 only when the sparse vectors match except for all zeros.

In the natural language processing in which the number of words is overwhelmingly smaller than the number of vocabularies, when the vocabulary is vectorized, sparse vectors are generated. Therefore, the information processing apparatus 10 according to the present embodiment can be effectively applied to determine whether sparse vectors match or are similar in the natural language processing.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. An information processing apparatus comprising a string connected to a first wiring and connected to a plurality of second wirings, wherein
the string includes a plurality of transistors connected in series, one end of the string connected to the first wiring, gates of the transistors connected to different second wirings,
the plurality of transistors include a first transistor and a second transistor,
the first transistor is set to a first threshold corresponding to first data,
the second transistor is set to a second threshold corresponding to second data having a complementary relationship with the first data,
two second wirings among the plurality of second wirings are connected to gates of the first transistor and the second transistor,
one of the two second wirings is set to a potential level corresponding to third data, and another is set to a potential level corresponding to fourth data having a complementary relationship with the third data, and
the string does not allow a current to flow when the first data and the third data match at a predetermined value, and allows the current to flow when the first data and the third data match at a value other than the predetermined value.

2. The information processing apparatus according to claim 1, wherein
when the first data and the third data match at the predetermined value, the first transistor is turned off, and
when the first data and the third data match at the value other than the predetermined value, the first transistor and the second transistor are turned on.

3. The information processing apparatus according to claim 2, wherein
when the first data and the third data match at the predetermined value, a gate voltage of the first transistor is lower than the first threshold, and
when the first data and the third data match at the value other than the predetermined value, the gate voltage of the first transistor becomes a potential level higher than the first threshold, and a gate voltage of the second transistor becomes a potential level higher than the second threshold.

4. The information processing apparatus according to claim 1, wherein
when the first data and the third data match at the predetermined value, one of the first transistor and the second transistor is turned on and another is turned off, and
when the first data and the third data match at the value other than the predetermined value, the first transistor and the second transistor are turned on.

5. The information processing apparatus according to claim 1, wherein
the predetermined value is zero.

6. The information processing apparatus according to claim 4, wherein
the predetermined value is zero, and
a potential level of a second wiring corresponding to the fourth data among the two second wirings in a case where the second transistor is turned on when the first data is 1 is same as a potential level of a second wiring corresponding to the fourth data in a case where the second transistor is turned off when the first data is zero.

7. The information processing apparatus according to claim 1, wherein
potential levels of the first threshold and the second threshold are set depending on multi-values of three or more values, and
the two second wirings have multi-valued potential levels of three or more values.

8. The information processing apparatus according to claim 7, wherein
the string allows a current corresponding to a multi-valued level when the first data and the third data match.

9. The information processing apparatus according to claim 8, wherein
at least one of gate voltages of the first transistor and the second transistor and thresholds of the first transistor or the second transistor are adjusted depending on a value when the first data and the third data match.

10. The information processing apparatus according to claim 1, wherein
the first to fourth data have a same number of bits,
when the number of bits of the first to fourth data exceeds a predetermined bit length or when a ratio of bits taking a value other than the predetermined value in the first to fourth data exceeds a predetermined value, a plurality of the strings corresponding to a plurality of divided bit strings obtained by dividing each of the first to fourth data into a plurality of pieces are provided, and
the plurality of strings are connected to a same first wiring.

11. The information processing apparatus according to claim 10, wherein
each of the plurality of divided bit strings includes at most one element other than the predetermined value.

12. The information processing apparatus according to claim 1, wherein
the string has a plurality of sets of the first transistors and the second transistors connected to each other with the first transistor and the second transistor as one set, and
each of the plurality of sets allows the current to flow when values of corresponding elements of the first data and the third data are same.

13. The information processing apparatus according to claim 12, wherein
a plurality of the first thresholds and a plurality of the second thresholds in the plurality of sets are set depending on values of corresponding digits of values obtained by converting the first data and the third data other than the predetermined value into an m-ary number (m is an integer less than 10 and 2 or more), and
the string allows the current to flow when each of the plurality of pieces of third data input to the plurality of sets is equal to the first data corresponding to the first threshold and each of the plurality of pieces of fourth data input to the plurality of sets is equal to the second data corresponding to the second threshold.

14. The information processing apparatus according to claim 1, further comprising
a detector configured to detect at least one of a current flowing through the first wiring or a voltage of the first wiring.

15. The information processing apparatus according to claim 1, wherein
the first wiring is a bit line,
the second wiring is a word line, and
the information processing apparatus includes a nonvolatile memory having a plurality of the strings.

16. The information processing apparatus according to claim 15, wherein
the nonvolatile memory is a NAND flash memory, and
charges depending on corresponding bits of the first data and the second data are accumulated in charge accumulation regions of the first transistor and the second transistor.

17. A memory system comprising:
a nonvolatile memory; and
a controller configured to control writing and reading of data to and from the nonvolatile memory, wherein
the nonvolatile memory includes a string connected to a first wiring and connected to a plurality of second wirings,
the string includes a plurality of transistors connected in series, one end of the string connected to the first wiring,
gates of the transistors connected to different second wirings,
the plurality of transistors include a first transistor and a second transistor,
the first transistor is set to a first threshold corresponding to first data,
the second transistor is set to a second threshold corresponding to second data having a complementary relationship with the first data,
two second wirings among the plurality of second wirings are connected to gates of the first transistor and the second transistor,
one of the two second wirings is set to a potential level corresponding to third data, and another is set to a potential level corresponding to fourth data having a complementary relationship with the third data, and
the string does not allow a current to flow when the first data and the third data match at a predetermined value, and allows the current to flow when the first data and the third data match at a value other than the predetermined value.

18. The memory system according to claim 17, wherein
when the first data and the third data match at the predetermined value, the first transistor is turned off, and
when the first data and the third data match at the value other than the predetermined value, the first transistor and the second transistor are turned on.

19. The memory system according to claim 18, wherein
when the first data and the third data match at the predetermined value, a gate voltage of the first transistor is lower than the first threshold, and
when the first data and the third data match at the value other than the predetermined value, the gate voltage of the first transistor becomes a potential level higher than the first threshold, and a gate voltage of the second transistor becomes a potential level higher than the second threshold.

20. The memory system according to claim 17, wherein
when the first data and the third data match at the predetermined value, one of the first transistor and the second transistor is turned on and another is turned off, and
when the first data and the third data match at the value other than the predetermined value, the first transistor and the second transistor are turned on.
